(19) United States
(12) Patent Application Publication
(10) Pub. No.: US 2026/0314463 A1
(43) Pub. Date: Oct. 8, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventor: Yoshiki ENDO, Kawasaki Kanagawa (JP)

(21) Appl. No.: 19/531,548

(22) Filed: Feb. 5, 2026

(30) Foreign Application Priority Data
Apr. 7, 2025 (JP) 2025-063320

(51) Int. Cl. H10W 72/20; H10D 80/20; H10W 40/22; H10W 70/40; H10W 72/00; H10W 74/10; H10W 90/00; H10W 90/10

(52) U.S. Cl. CPC H10W 72/234; H10D 80/251; H10W 40/226; H10W 70/429; H10W 70/481; H10W 72/232; H10W 72/265; H10W 72/859; H10W 74/114; H10W 90/10; H10W 90/726; H10W 90/756

(57) ABSTRACT

A semiconductor device according to embodiments comprises: a first electrode; a semiconductor element provided on the first electrode; a second electrode provided on the semiconductor element, the second electrode having a lower surface facing the semiconductor element, and having an upper surface opposite to the lower surface of the second electrode; and a third electrode overlapping the second electrode in a first direction that extends from the first electrode toward the first semiconductor element, a lower surface of the third electrode being located farther from the semiconductor element than the lower surface of the second electrode in the first direction, and an upper surface of the third electrode being located closer to the semiconductor element than the upper surface of the second electrode in the first direction.

### CROSS-REFERENCE TO RELATED APPLICATION

This application is based upon and claims the benefit of priority from Japanese Patent Application No. 2025-063320, filed on Apr. 7, 2025; the entire contents of which are incorporated herein by reference.

### FIELD

Embodiments described herein relate generally to a semiconductor device.

### BACKGROUND

In a semiconductor package, a structure is known in which a semiconductor chip is provided between a heat sink connected to an emitter electrode and a heat sink connected to a collector electrode.

### BRIEF DESCRIPTION OF THE DRAWINGS

FIG. 1 is a top view of a semiconductor device according to a first embodiment.

FIG. 2A is a top view of the semiconductor device according to the first embodiment with resin being transparent.

FIG. 2B is a perspective view of the semiconductor device according to the first embodiment with resin omitted.

FIG. 3A is a top view of a first modification of the first embodiment with resin being transparent.

FIG. 3B is a perspective view of the first modification of the first embodiment with resin omitted.

FIGS. 4A-4C show third electrodes of the semiconductor device according to the first embodiment.

FIG. 5 is a cross-sectional view taken along line A1–A2 of the semiconductor device according to the first embodiment.

FIG. 6 is a cross-sectional view taken along line L1–L2 of the semiconductor device according to the first embodiment.

FIG. 7 is a cross-sectional view taken along line I1–I2 of the semiconductor device according to the first embodiment.

FIG. 8A is a top view of a semiconductor device according to a second embodiment with resin being transparent.

FIG. 8B is a cross-sectional view taken along line J1–J2 of the semiconductor device according to the second embodiment.

FIG. 9 is a perspective view of a semiconductor device according to a third embodiment with resin omitted.

FIG. 10 is a cross-sectional view taken along line M1–M2 of the semiconductor device according to the third embodiment.

FIG. 11 is a perspective view of a first modification of the third embodiment with resin omitted.

FIG. 12 is a cross-sectional view taken along line N1–N2 of the first modification of the third embodiment.

FIG. 13 is a perspective view of a semiconductor device according to a fourth embodiment with resin omitted.

FIG. 14A is a top view of the semiconductor device according to the fourth embodiment with resin being transparent.

FIG. 14B is a top view of a first modification of the fourth embodiment with resin being transparent.

FIG. 15 is a cross-sectional view taken along line B1–B2 of the semiconductor device according to the fourth embodiment.

FIG. 16 is a top view of a second modification of the fourth embodiment with resin being transparent.

FIG. 17 is a top view of a semiconductor device according to a fifth embodiment.

FIG. 18 is a cross-sectional view taken along line C1–C2 of the semiconductor device according to the fifth embodiment.

FIG. 19 is a cross-sectional view of a first modification of the fifth embodiment.

FIG. 20 is a top view of a semiconductor device according to a sixth embodiment with resin being transparent.

FIG. 21 is a top view of a semiconductor device according to a seventh embodiment with resin being transparent.

FIG. 22 is a cross-sectional view taken along line D1–D2 of the semiconductor device according to the seventh embodiment.

FIGS. 23A-23F are perspective views showing an example of the second electrode.

### DETAILED DESCRIPTION

A semiconductor device according to embodiments comprises: a first electrode; a semiconductor element provided on the first electrode; a second electrode provided on the semiconductor element, the second electrode having a lower surface facing the semiconductor element, and having an upper surface opposite to the lower surface of the second electrode; and a third electrode overlapping the second electrode in a first direction that extends from the first electrode toward the semiconductor element, a lower surface of the third electrode being located farther from the semiconductor element than the lower surface of the second electrode in the first direction, and an upper surface of the third electrode being located closer to the semiconductor element than the upper surface of the second electrode in the first direction.

Hereinafter, embodiments will be described with reference to the drawings.

Note that the drawings are schematic or conceptual, and the relationships between thickness and width of each part, and the size ratios between parts, are not necessarily identical to actual ones. Even for the same part, dimensions and ratios may differ depending on the drawing.

In the present specification and drawings, identical reference numerals are assigned to elements that are the same as those described in previously mentioned drawings, and detailed descriptions thereof may be omitted as appropriate.

A direction that extends from the first electrode 10 toward the second electrode 20 is referred to as a “Z direction.” A direction orthogonal to the Z direction is referred to as an “X direction,” and a direction intersecting both the X and Z directions is referred to as a “Y direction.” Although the X, Y, and Z directions are shown as being orthogonal in embodiments, they are not limited to orthogonal relationships. For the sake of explanation, the positive direction of the Z axis is referred to as “up,” and the negative direction opposite to the positive direction is referred to as “down.” However, “up” and “down” are not limited to the direction of gravity or the orientation during mounting of the semiconductor device.

### First Embodiment

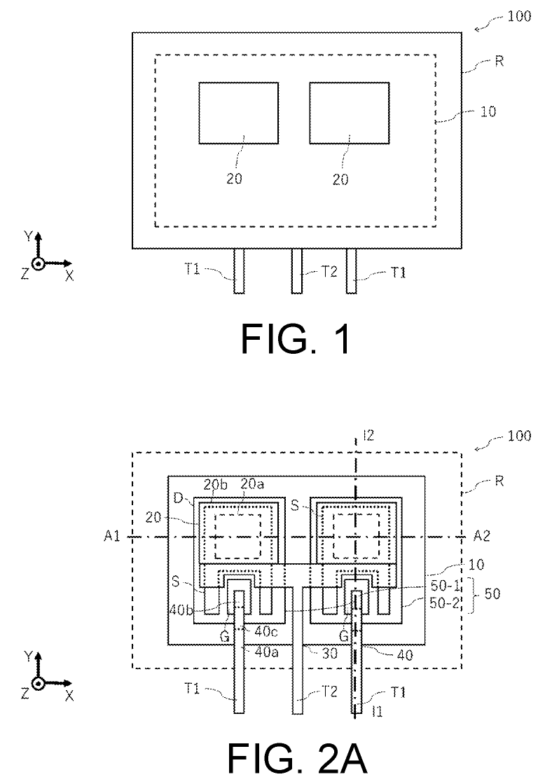

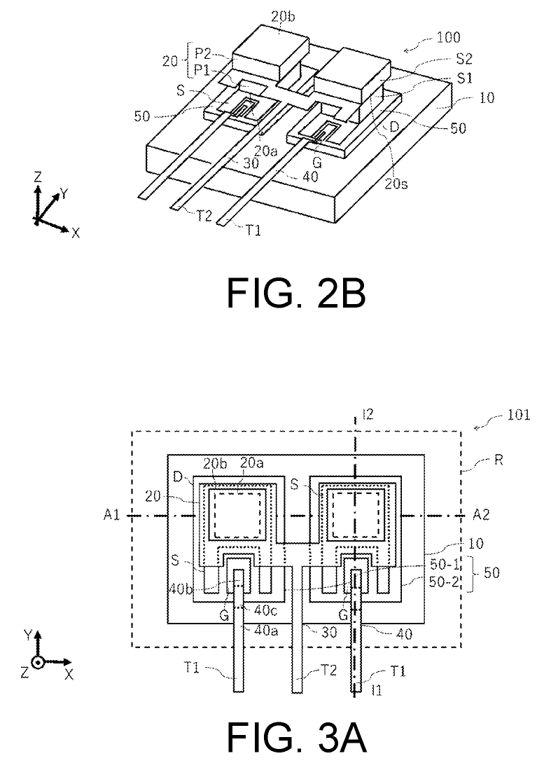

FIG. 1 is a top view showing a semiconductor device 100 according to the first embodiment. FIG. 2A is a top view showing the semiconductor device 100 with resin R (indicated by a dashed region in FIG. 2) being transparent.

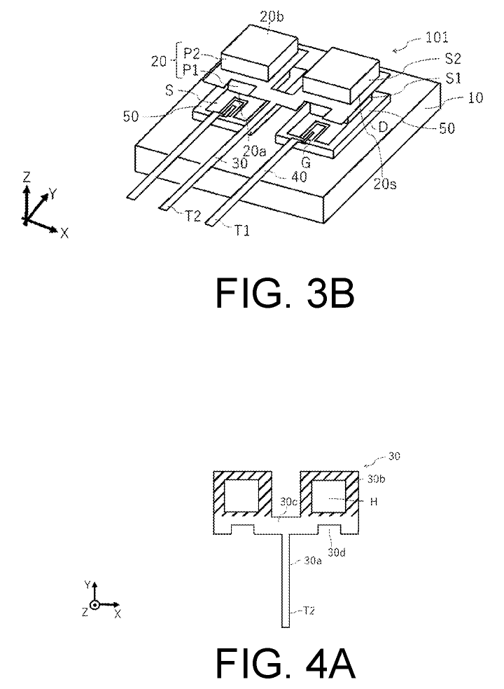

The semiconductor device 100 includes a semiconductor element 50 (see FIG. 3B) sealed with resin R. The resin R surrounds the semiconductor element 50 in a plane perpendicular to the Z direction. The resin R is an insulating material that covers the semiconductor element 50. The semiconductor element 50 includes a transistor. For example, the semiconductor element 50 may include a MOSFET (Metal Oxide Semiconductor Field Effect Transistor).

The semiconductor device 100 includes a first electrode 10 on a lower surface (located in the negative direction of the Z axis). As shown in FIG. 1, the semiconductor device 100 includes one or more second electrodes 20 on an upper surface (located in the positive direction of the Z axis). The one or more second electrodes 20 may be provided in plural as shown in FIG. 1, or may be provided as a single electrode. Herein, items such as the one or more second electrodes 20 are sometimes referred to in the singular for simplicity, e.g., “the second electrode 20,” to refer to each instance of such item. The first electrode 10 may be, for example, at a drain potential of the MOSFET. The second electrode 20 may be, for example, at a source potential of the MOSFET.

The semiconductor device 100 includes one or more first terminals T1 and a second terminal T2 protruding from a side surface of the package, the side surface extending in a direction that intersects the Y direction in FIG. 1. The one or more first terminals T1 may be provided in the same number as the one or more second electrodes 20. The number of second electrodes 20 and first terminals T1 may be equal to the number of semiconductor chips including MOSFETs provided in the semiconductor device 100. The first terminal T1 may be, for example, a gate terminal of the MOSFET.

The second terminal T2 may be, for example, a terminal for sensing the potential of the source electrode of the MOSFET. The second terminal T2 is electrically connected to the source electrode of the MOSFET.

Next, the description will be made with reference to FIG. 2A. FIG. 2A is a top view showing the semiconductor device 100 with resin R (indicated by a dashed region in FIG. 2A) being transparent.

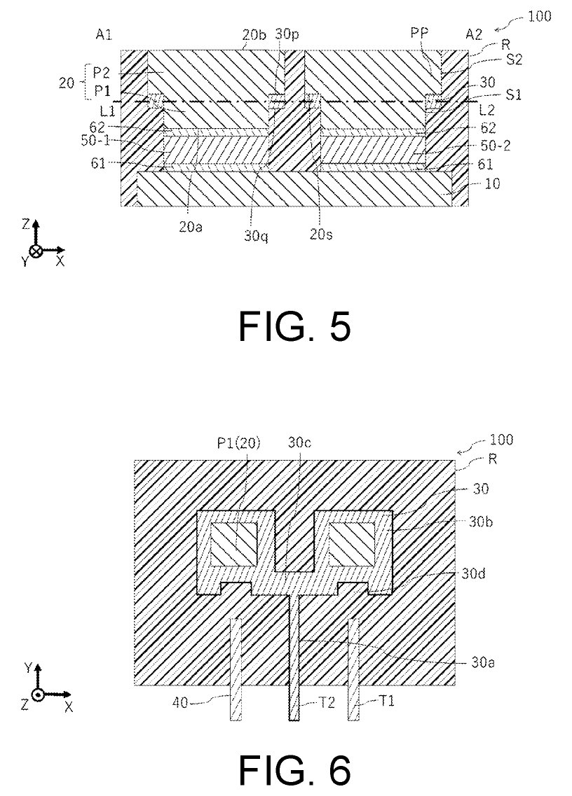

On the first electrode 10, semiconductor elements 50 including a first semiconductor element 50-1 and a second semiconductor element 50-2 are provided. Hereinafter, the term “semiconductor element 50” may refer to either the first semiconductor element 50-1 and the second semiconductor element 50-2. A bonding layer 61 (see FIG. 5), for example, may be provided between the first electrode 10 and the semiconductor element 50. The semiconductor element 50 includes a drain electrode D on its lower surface, and a source electrode S and a gate electrode G on its upper surface. The source electrode S may be, for example, a source pad, and the gate electrode G may be, for example, a gate pad. In FIG. 2A, the region where the source electrode S overlaps with the second electrode 20 and the third electrode 30 is indicated by a dotted outline. Although the terms drain electrode D, source electrode S, and gate electrode G are used for explanation, the semiconductor element 50 is not necessarily a MOSFET. If the semiconductor element 50 is an IGBT, the drain electrode D corresponds to a collector electrode, and the source electrode S corresponds to an emitter electrode.

The second electrode 20 is provided on the semiconductor element 50. The second electrode 20 is electrically connected to the source electrode S. A bonding layer 62 (see FIG. 5), for example, may be provided between the second electrode 20 and the semiconductor element 50. The second electrode 20 has a first surface 20a located on the lower side in the Z direction, facing the semiconductor element 50. The first surface 20a is indicated by a dashed outline in FIG. 2A. The second surface 20b of the second electrode 20 is located on the upper side in the Z direction, opposite to the first surface 20a, and is exposed from the resin R as shown in FIG. 1.

The length of the second electrode 20 in the X direction at the first surface 20a is smaller than that at the second surface 20b. The length of the second electrode 20 in the Y direction at the first surface 20a is smaller than that at the second surface 20b. The area of the second electrode 20 in the XY plane at the first surface 20a is smaller than that at the second surface 20b.

As shown in FIG. 2A, the second electrode 20 is connected to the third electrode 30. The connection between the second electrode 20 and the third electrode 30 includes not only electrical connection but also bonding via an insulating material. For example, the second electrode 20 and the third electrode 30 may be electrically connected. FIG. 2A shows an example in which the third electrode 30 and the second terminal T2 protruding from the resin R are provided continuously. Also, FIG. 2A shows an example in which the gate electrode G is connected to the fourth electrode 40 and the first terminal T1, which are protruding from the resin R and provided continuously.

FIG. 2B shows a perspective view of the semiconductor device 100 according to the first embodiment. The resin R is omitted in the drawing.

The second electrode 20 includes a first portion P1 including the first surface 20a, and a second portion P2 including the second surface 20b. In FIG. 2B, the first surface 20a is included in the first portion P1, and the second surface 20b is included in the second portion P2; however, as will be described later with reference to FIG. 11, embodiments are not limited to this configuration. The length of the first portion P1 in the X direction is smaller than that of the second portion P2. The length of the first portion P1 in the Y direction is smaller than that of the second portion P2.

The first portion P1 has first side surfaces S1. The second portion P2 has second side surfaces S2. The first side surfaces S1 surround the first portion P1 in the XY plane. The second side surfaces S2 surround the second portion P2 in the XY plane. The first and second side surfaces S1 and S2 include surfaces intersecting the X direction and surfaces intersecting the Y direction.

As will be described later with reference to FIG. 5, the first side surfaces S1 and the second side surfaces S2 are connected by step surfaces 20s. The step surfaces 20s intersect the first and second side surfaces S1 and S2. In the example shown in FIG. 2B, the step surfaces 20s are the lower surfaces of the second portion P2. The second electrode 20 is connected to and overlaps the third electrode 30 at the step surfaces 20s. The step surfaces 20s face the semiconductor element 50 in the negative Z direction.

The third electrode 30 is located apart from both the first surface 20a and the second surface 20b in the Z direction. The position of the third electrode 30 in the Z direction differs from that of the first surface 20a. The position of the third electrode 30 in the Z direction also differs from that of the second surface 20b. The third electrode 30 is located between the first surface 20a and the second surface 20b in the Z direction. The entire third electrode 30 is located apart from both the first surface 20a and the second surface 20b in the Z direction.

The fourth electrode 40 is connected to the gate electrode G. The fourth electrode 40 has a bent structure extending in the positive direction of the Z axis from the portion connected to the gate electrode G toward the first terminal T1. The positions of the first terminal T1 and the second terminal T2 in the Z direction may be made equal.

The description of the first embodiment is based on the shape of the third electrode 30 shown in FIGS. 2A and 2B. However, as in the modified example of the semiconductor device 101 shown in FIGS. 3A and 3B, the outer shape of the third electrode 30 in the XY plane may be larger than the outer shape of the second portion P2 of the second electrode 20. FIG. 3A is a top view of the semiconductor device 101 with resin R being transparent. FIG. 3B is a perspective view of the semiconductor device 101 with resin R omitted. The third electrode 30 includes a portion protruding further than the second electrode 20 in the top view through the resin R. The third electrode 30 includes portions protruding in the X and Y directions further than the second electrode 20 in the top view through the resin R. Although the following description is based on the shape of the third electrode 30 shown in FIGS. 2A and 2B, embodiments include the configuration shown in FIGS. 3A and 3B.

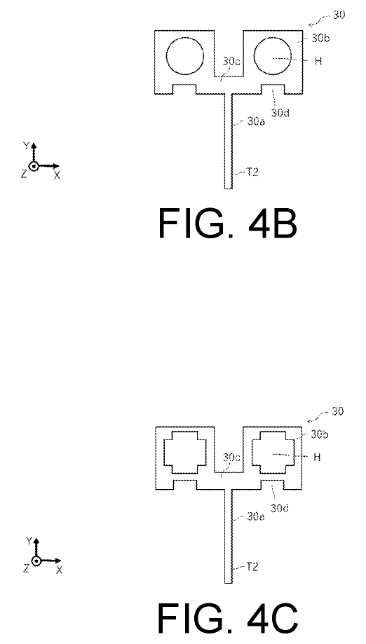

The shape of the third electrode 30 will be described with reference to FIG. 4A. Although the example includes two semiconductor elements 50, namely the first semiconductor element 50-1 and the second semiconductor element 50-2, the shape of the third electrode 30 is not limited to those shown in FIGS. 4A to 4C. In FIG. 4A, the hatched portion indicates the part overlapping with the second electrode 20 and not shown in FIGS. 2A and 2B.

The third electrode 30 is a plate-shaped conductor having a plane perpendicular to the Z direction. The third electrode 30 extends in a direction perpendicular to the Z direction without bending. The third electrode 30 includes a first region 30a continuous with the second terminal T2, i.e., extending to the second terminal T2. The third electrode 30 includes a second region 30b (hatched) connected to the second electrode 20. The second region 30b may be, for example, in surface contact with the second electrode 20. The second region 30b may be provided in a ring shape with a hole H inside, as shown in FIG. 4A. For simplicity, the example with the hole H is described below, but the second region 30b is not necessarily ring-shaped and may include a notch instead of the hole H.

A third region 30c is provided between the first region 30a and the second region 30b. If there are two semiconductor elements 50, the third region 30c is a branch. The third electrode 30 may include a notch 30d at a position overlapping with the gate electrode G in the Z direction in FIGS. 2A and 2B. The notch 30d suppresses interference of the third electrode 30 with the fourth electrode 40. In other words, the notch 30d suppresses contact between the third electrode 30 and the fourth electrode 40.

The second terminal T2, the first region 30a, the second region 30b, and the third region 30c of the third electrode 30 shown in FIG. 4A may be provided on the same plane. That is, a plane may be defined such that at least a part of the second terminal T2, the first region 30a, the second region 30b, and the third region 30c lies on the plane. The second terminal T2 and the third electrode 30 may be formed in a flat shape. The second terminal T2 and the third electrode 30 may be integrally formed, i.e., formed as a single member.

FIGS. 4B and 4C show other examples of the shape of the third electrode 30.

For example, as shown in FIG. 4B, the contour of the hole H may include a curved shape. The hole H may be circular, elliptical, or oblong. Alternatively, as shown in FIG. 4C, the contour of the hole H may be a shape with corners cut off, such as a cross shape. That is, the shape of the hole H is not limited to a polygon and may be appropriately selected from various shapes. For example, the shape of the hole H, i.e., the shape of the second electrode 20, may be selected to match the shape of the source electrode S.

FIG. 5 is an XZ cross-sectional view taken along line A1–A2 shown in FIG. 2A.

The semiconductor element 50 is provided on the first electrode 10 via a bonding layer 61. The second electrode 20 is provided on the semiconductor element 50 via a bonding layer 62. The semiconductor element 50 includes a drain electrode D, a source electrode S, and a gate electrode G.

The second electrode 20 includes a first portion P1 and a second portion P2 on the first portion P1. The second electrode 20 may be, for example, integrally formed, i.e., formed as a single member. The length of the first portion P1 in the X direction is smaller than that of the second portion P2. The length of the first portion P1 in the Y direction is smaller than that of the second portion P2. The area of the first portion P1 in the XY plane is smaller than that of the second portion P2.

The second electrode 20 includes a first surface 20a overlapping the semiconductor element 50 and a second surface 20b located opposite to the first surface 20a in the Z direction and exposed from the resin R. The first surface 20a is the lower surface of the first portion P1, and the second surface 20b is the upper surface of the second portion P2. The second portion P2 includes a protruding portion PP protruding further in the X direction than the first portion P1. The protruding portion PP protrudes further than any part of the first portion in the X direction. The third electrode 30 overlaps the protruding portion PP in the Z direction.

The step surface 20s is the lower surface of the protruding portion PP of the second portion P2. The step surface 20s is a surface facing the negative Z direction within the second electrode 20, i.e., being oriented toward the negative direction of the Z axis. The step surface 20s is located between the first side surface S1 and the second side surface S2 and physically connects the first side surface S1 and the second side surface S2. The first and second side surfaces S1 and S2 extend in the Z direction. The step surface 20s extends in the XY plane intersecting the Z direction. For example, in the XY plane, the step surface 20s may be disposed around a perimeter of the first portion P1.

The upper surface 30p of the third electrode 30 is provided closer to the semiconductor element 50 in the Z direction than the second surface 20b of the second electrode 20. The upper surface 30p of the third electrode 30 is located in the negative direction of the Z axis relative to the second surface 20b. The upper surface 30p of the third electrode 30 is located between the first surface 20a and the second surface 20b of the second electrode 20 in the Z direction. The upper surface 30p faces at least a part of the step surface 20s of the second electrode 20.

The lower surface 30q of the third electrode 30 is the surface opposite to the upper surface 30p in the Z direction. The lower surface 30q is provided farther from the semiconductor element 50 in the Z direction than the first surface 20a of the second electrode 20. The lower surface 30q is located in the positive direction of the Z axis relative to the first surface 20a. The lower surface 30q is located between the first surface 20a and the second surface 20b of the second electrode 20 in the Z direction. The upper surface 30p and the lower surface 30q of the third electrode 30 are located apart from both the first surface 20a and the second surface 20b of the second electrode 20 in the Z direction.

The upper surface 30p of the third electrode 30 is located in the negative direction of the Z axis relative to the second surface 20b of the second electrode 20 and is provided closer to the semiconductor element 50 than the second surface 20b. The upper surface 30p is located between the first surface 20a and the second surface 20b of the second electrode 20 in the Z direction and faces at least a part of the step surface 20s.

The lower surface 30q of the third electrode 30 is the surface opposite to the upper surface 30p in the Z direction and is located in the positive direction of the Z axis relative to the first surface 20a of the second electrode 20. The lower surface 30q is provided farther from the semiconductor element 50 than the first surface 20a. The lower surface 30q is located between the first surface 20a and the second surface 20b of the second electrode 20 in the Z direction. The upper surface 30p and the lower surface 30q of the third electrode 30 are located apart from both the first surface 20a and the second surface 20b of the second electrode 20 in the Z direction.

The third electrode 30 is connected to and overlaps the second electrode 20 at a position between the first surface 20a and the second surface 20b in the Z direction. The third electrode 30 is connected to and overlaps the second portion P2 of the second electrode 20 at the step surface 20s. The third electrode 30 may be, for example, in surface contact with the second electrode 20 at the step surface 20s. The third electrode 30 is located in the negative direction of the Z axis relative to the second portion P2.

The connection between the second electrode 20 and the third electrode 30 may be made by welding, such as laser welding. Alternatively, the second electrode 20 and the third electrode 30 may be connected via a conductive material including Ag, such as silver paste, thus overlapping in the Z direction with the conductive material interposed therebetween. The connection may also be made by sintering or via a bonding material such as solder. As will be described later, for inspection of the bonding layers 61 and 62, it is preferable to connect the second electrode 20 and the third electrode 30 by welding, sintering, or silver paste. In the case of the configuration shown in FIG. 11 described later, the second electrode 20 and the third electrode 30 may be connected via an insulating material, thus overlapping in the Z direction with the insulating material interposed therebetween. For example, as shown in FIG. 11, if the second terminal T2 and the source electrode S are connected by a wire W, the second electrode 20 and the third electrode 30 may be bonded by an insulating material.

FIG. 6 is an XY plan view taken along line L1–L2 shown in FIG. 5.

The line L1–L2 is located on a plane passing through the third electrode 30. The third electrode 30 surrounds the first portion P1 of the second electrode 20. The first portion P1 of the second electrode 20 is located between the second regions 30b in the X direction. The first portion P1 of the second electrode 20 is located between the second regions 30b in the Y direction. The first portion P1 of the second electrode 20 is surrounded by the second regions 30b in the XY plane.

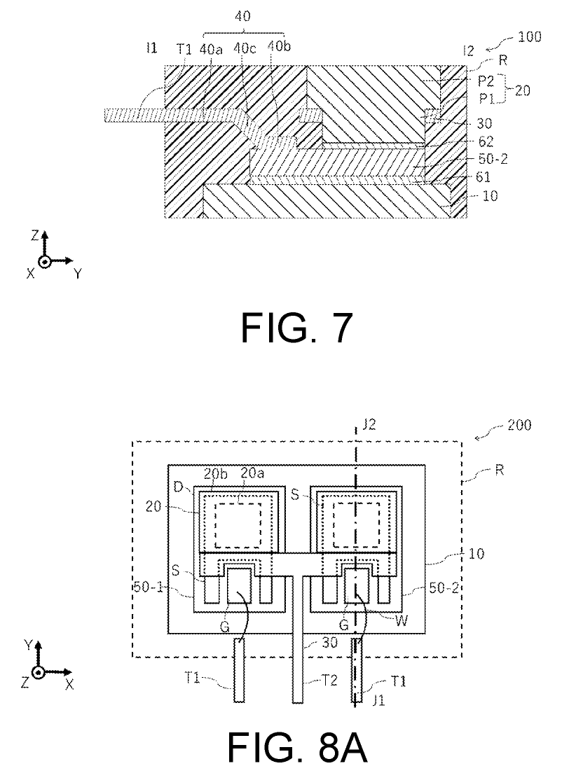

FIG. 7 is a YZ cross-sectional view taken along line I1–I2 shown in FIG. 2. Although the gate electrode G is omitted in FIG. 7, it is included in the second semiconductor element 50-2.

The fourth electrode 40 and the first terminal T1 are provided continuously. The fourth electrode 40 includes a first portion 40a adjacent to the first terminal T1, a second portion 40b connected to the gate electrode G, and a third portion 40c located between the first portion 40a and the second portion 40b. The connection between the fourth electrode 40 and the gate electrode G provided in the semiconductor element 50-2 may be made via a bonding material such as solder.

The third portion 40c of the fourth electrode 40 is a bent portion located between the first terminal T1 and the semiconductor element 50-2. For example, if the positions of the first portion 40a and the second portion 40b in the Z direction differ, the third portion 40c connects the first portion 40a and the second portion 40b.

In the manufacturing process, the first terminal T1, the second terminal T2, the third electrode 30, and the fourth electrode 40 are prepared as a lead frame. The first terminal T1, the second terminal T2, the third electrode 30, and the first portion 40a of the fourth electrode 40 are provided at the same position in the Z direction. In other words, the first terminal T1, the second terminal T2, the third electrode 30, and the first portion 40a of the fourth electrode 40 include portions provided on the same plane orthogonal to the Z direction. The second portion 40b may be formed by bending a part of the lead frame (corresponding to the third portion 40c) to adjust its position in the Z direction.

Examples of materials for each component of the first embodiment will be described.

The semiconductor element 50 may include, for example, Si or SiC as a semiconductor material. The first electrode 10 and the second electrode 20 may include, for example, at least one of Cu, Mo, or Al as conductive materials. The first electrode 10 and the second electrode 20 may include, for example, at least one of Cu, CuMo, or AlSiC. The third electrode 30 and the fourth electrode 40 may include, for example, Cu as a metal. The third electrode 30 and the fourth electrode 40 may include the same material.

The bonding layers 61 and 62 may be, for example, Pb-based solder or Sn-based solder. The bonding layers 61 and 62 may also be silver paste or sintered material. The resin R is a sealing resin and may include, for example, epoxy resin.

According to the semiconductor device 100 of the first embodiment, a semiconductor device with reduced thermal resistance can be provided. The second electrode 20 provided on the semiconductor element 50 serves as a heat dissipation path for heat generated in the semiconductor element 50. The second electrode 20 is an integrated structure (i.e., a single member) and does not require other internal components. By using the second electrode 20 as a heat dissipation path to the outside of the resin R, thermal resistance can be further reduced compared to a configuration in which a bonding layer and a heat sink are further provided on the second electrode 20.

The third electrode 30 may be located, for example, surrounding the outer periphery of the second electrode 20 in the XY plane. One of the main heat dissipation paths from the semiconductor element 50 is a path through the second electrode 20 in the positive direction of the Z axis. The contact between the second electrode 20 and the third electrode 30 is positioned outside the main heat dissipation paths, reducing the influence by the third electrode 30 on heat dissipation. The current path flowing between the semiconductor element 50 and the second surface 20b of the second electrode 20 does not need to pass through the third electrode 30.

Furthermore, according to the semiconductor device 100 of the first embodiment, quality control of the semiconductor device can be more easily performed, and reliability of the semiconductor device can be further improved. Quality control of the semiconductor device may include, for example, detecting the quality of formation of the bonding layers 61 and 62. The quality of formation of the bonding layers 61 and 62 may be determined by inspection using X-rays or ultrasonic waves (hereinafter referred to as “inspection waves”) from the upper and lower surfaces of the semiconductor device 100.

When inspecting from the upper surface of the semiconductor device 100, since there is no additional bonding layer above the bonding layer 62 shown in FIG. 5, the bonding layer 62 can be accurately inspected by inspection waves passing through the second electrode 20. Therefore, the quality of formation of the bonding layer 62 can be accurately determined, improving quality control and reliability of the semiconductor device.

For comparison, if a heat sink is provided above the second electrode 20 via a bonding layer, inspection from the upper surface of the semiconductor device may be interfered with by an additional bonding layer between the heat sink and the second electrode 20 above the bonding layer 62. In particular, the additional bonding layer may reflect or absorb the inspection wave, making it difficult to inspect the bonding layer 62 with sufficient accuracy.

On the other hand, according to the semiconductor device 100 of the first embodiment, quality control and reliability can be further improved compared to the configuration where the heat sink is provided above the second electrode 20 via the additional bonding layer.

In addition, in the first embodiment, the third electrode 30 may be located, for example, surrounding the outer periphery of the second electrode 20 in the XY plane. The connection portion between the second electrode 20 and the third electrode 30 has a low risk of interfering with the inspection wave when inspecting the bonding layer 62 from the upper surface of the semiconductor device 100 because the connection portion and the bonding layer 62 do not overlap in the Z direction. Even if the second electrode 20 and the third electrode 30 are connected by solder or the like, interference with the inspection wave can be suppressed, and inspection accuracy can be improved.\

### Second Embodiment

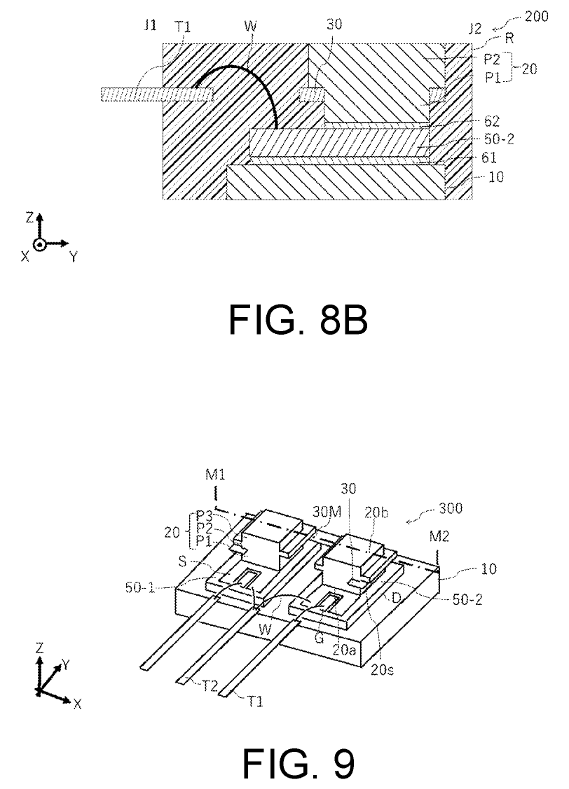

FIG. 8A is a top view showing a semiconductor device 200 according to the second embodiment with resin R being transparent. FIG. 8B is a YZ cross-sectional view taken along line J1–J2 shown in FIG. 8A. Description of portions common to the semiconductor device 100 of the first embodiment is partially omitted.

In the second embodiment, the connection between the first terminal T1 and the gate electrode G is made via a wire W formed by wire bonding. The cross-section of the wire W is not limited to a circular shape and may be a flat or ribbon-like shape having a long side and a short side. That is, a sheet-like conductive material such as a ribbon may be used as the wire W.

As shown in FIG. 8A, the first terminal T1 is electrically connected to the gate electrode G of the semiconductor element 50-2 via the wire W. As shown in FIG. 8B, the positions of the second terminal T2 and the first terminal T1 in the Z direction may be made equal. The first terminal T1, the second terminal T2, the third electrode 30, and the fourth electrode 40 are included in a flat lead frame in the manufacturing process. That is, the first terminal T1, the second terminal T2, the third electrode 30, and the fourth electrode 40 are prepared as a flat lead frame, and then the first terminal T1, the third electrode 30, and the fourth electrode 40 are separated to obtain the third electrode 30 and the fourth electrode 40 electrically insulated from each other as shown in FIGS. 8A and 8B.

According to the semiconductor device 200 of the second embodiment, the third electrode 30 and the fourth electrode 40 can be formed from a flat lead frame, thus eliminating the process of bending the lead frame between the third electrode 30 and the second terminal T2, and between the fourth electrode 40 and the first terminal T1, and thus reducing the overall bending of the lead frame. By reducing the number of bending processes for the lead frame, the number of bent portions of the lead frame can be reduced. As a result, when sealing the lead frame with resin R, the volume of resin R required can be reduced, and the package size can be further reduced.

In the second embodiment, the second terminal T2 is continuous with the third electrode 30 and electrically connected to the source electrode S via the third electrode 30. Alternatively, the second terminal T2 may be electrically connected to the source electrode S via a wire. That is, the second terminal T2 and the source electrode S may be electrically connected by a wire. Specific examples of such configurations are described in, for example, FIG. 9.

### Third Embodiment

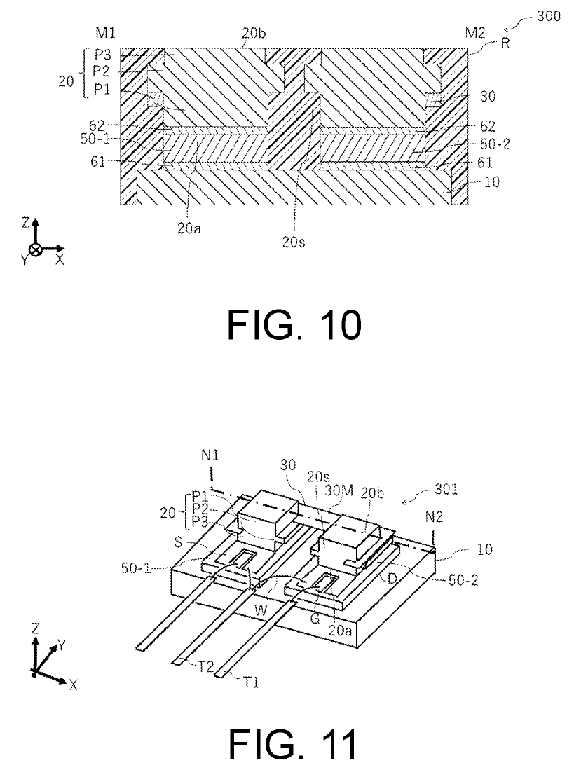

FIG. 9 is a perspective view of a semiconductor device 300 according to the third embodiment with resin R omitted. FIG. 10 is an XZ cross-sectional view taken along line M1–M2 shown in FIG. 9. Description of portions common to the semiconductor device 100 of the first embodiment is partially omitted.

Referring to FIG. 9, the second electrode 20 of the semiconductor device 300 includes a first portion P1 on the semiconductor element 50, a second portion P2 on the first portion P1, and a third portion P3 on the second portion P2. The second electrode 20 may be, for example, integrally formed, i.e., formed as a single member. The second electrode 20 and the third electrode 30 are connected and face each other at the lower surface of the second portion P2. The step surface 20s is the lower surface of the second portion P2. The second electrode 20 and the third electrode 30 are connected and face each other at the step surface 20s.

In FIG. 9, the second terminal T2 and the source electrode S are electrically connected via a wire W. That is, the second terminal T2 and the third electrode 30 do not need to be continuous.

The third electrode 30 located above the first semiconductor element 50-1 and the third electrode 30 located above the second semiconductor element 50-2 are connected via an intermediate portion 30M of the third electrode 30. The line M1–M2 shown in FIG. 9 is located in the negative direction of the Y axis relative to the intermediate portion 30M, and the cross-section shown in FIG. 10 does not pass through the intermediate portion 30M.

The length of the third portion P3 in the X direction is smaller than that of the second portion P2. The length of the third portion P3 in the Y direction is smaller than that of the second portion P2. The area of the third portion P3 in the XY plane is smaller than that of the second portion P2.

A larger area of the third portion P3 in the XY plane is desirable because it increases the exposed area of the second electrode 20 on the upper surface thereof. For example, the area of the third portion P3 in the XY plane may be larger than that of the first portion P1.

According to the semiconductor device 300 of the third embodiment, the adhesion strength between the second electrode 20 and the resin R can be improved. The second portion P2 protrudes from the first portion P1 and the third portion P3. The second portion P2 includes a protruding portion PP protruding further than any part of the third portion P3 in the X direction. The second portion P2 of the second electrode 20 protrudes into the resin R, resulting in strong adhesion between the resin R and the second electrode 20. Even if a force acts to peel the second electrode 20 from the resin R in the positive direction of the Z axis, the peeling of the second electrode 20 from the resin R can be suppressed.

Furthermore, according to the semiconductor device 300 of the third embodiment, further miniaturization of the package is possible. The first terminal T1 and the second terminal T2 are connected to the gate electrode G and the source electrode S via wires W, respectively. In the manufacturing process, it is not necessary to bend the lead frame between the third electrode 30 and the second terminal T2, and between the fourth electrode 40 and the first terminal T1. The third electrode 30, the first terminal T1, and the second terminal T2 can be formed from a flat lead frame. By reducing the bent portions of the lead frame, the volume of resin R required for sealing the semiconductor package can be reduced.

That is, according to the semiconductor device 300 of the third embodiment, further miniaturization of the package is possible. In the third embodiment, the third electrode 30 may be formed, for example, in a flat shape. In the manufacturing process, the number of bending processes for the lead frame including the third electrode 30 can be reduced. When the lead frame is bent, it may be necessary to seal the bent portion with resin R. According to the semiconductor device 300 of the third embodiment, the volume of resin R required for sealing the lead frame with resin R, i.e., the package volume, can be reduced.

For comparison, if the positions of the third electrode 30 and the second terminal T2 in the Z direction differ, and bending is required between the third electrode 30 and the second terminal T2, bending is required between the third electrode 30 and the second terminal T2. Compared to the third embodiment, the amount of bending for the lead frame increases. If a bent portion is present between the third electrode 30 and the second terminal T2, it becomes necessary to seal the bent portion with resin. Therefore, including the bent portion in the package may require increasing the package size further than a package of the third embodiment.

On the other hand, in the third embodiment, the position of the third electrode 30 in the Z direction can be adjusted to match the desired positions of the first terminal T1 and the second terminal T2 in the Z direction. Here, the desired protrusion position of the second terminal T2 may be predetermined based on the package design. That is, the connection position between the second electrode 20 and the third electrode 30 along the Z direction can be adjusted so that the third electrode 30 can be formed in a flat shape.

### First Modification of Third Embodiment

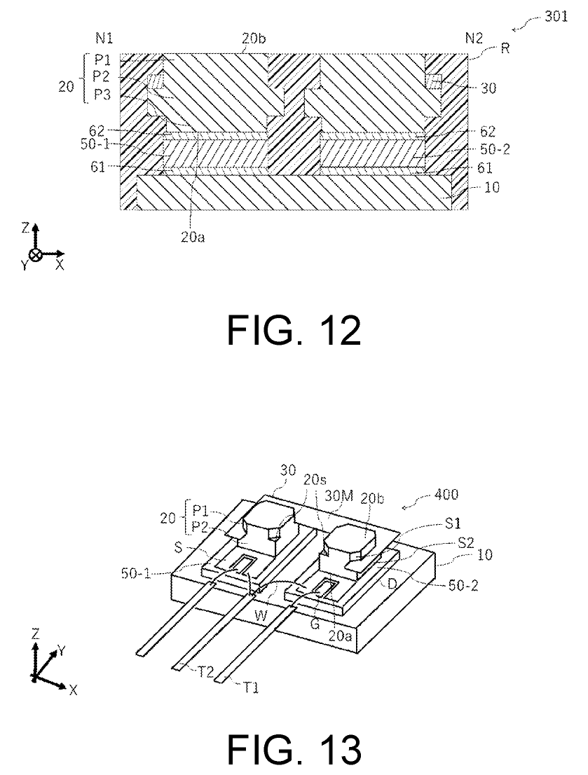

FIG. 11 is a perspective view of a semiconductor device 301 according to a first modification of the third embodiment with resin R omitted. FIG. 12 is an XZ cross-sectional view taken along line N1–N2 shown in FIG. 11. Description of portions common to the semiconductor device 300 of the third embodiment is partially omitted.

In the first modification of the third embodiment, the second electrode 20 includes a third portion P3 on the semiconductor elements 50, a second portion P2 on the third portion P3, and a first portion P1 on the second portion P2. The second electrode 20 and the third electrode 30 are connected and face each other at the lower surface of the second portion P2. In the first modification of the third embodiment, the step surface 20s is the upper surface of the second portion P2. The second electrode 20 and the third electrode 30 are connected and face each other at the step surface 20s.

According to the semiconductor device 301 of the first modification of the third embodiment, the adhesion strength between the second electrode 20 and the resin R can also be improved.

### Fourth Embodiment

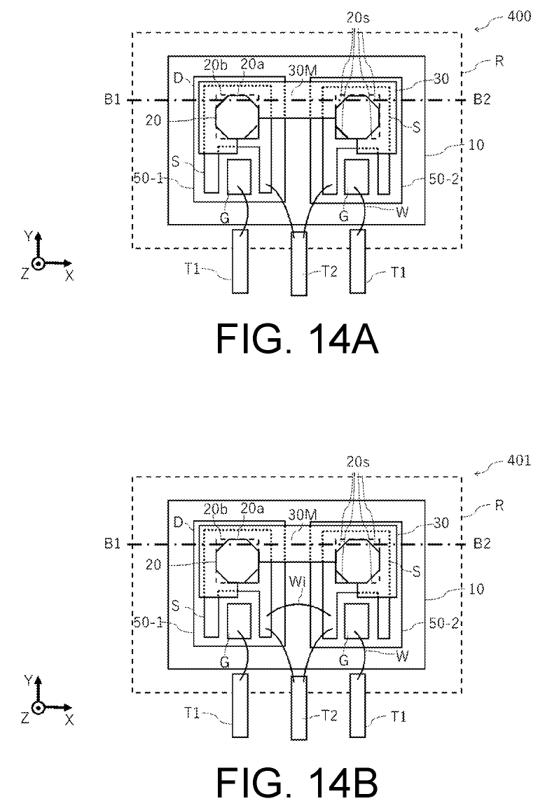

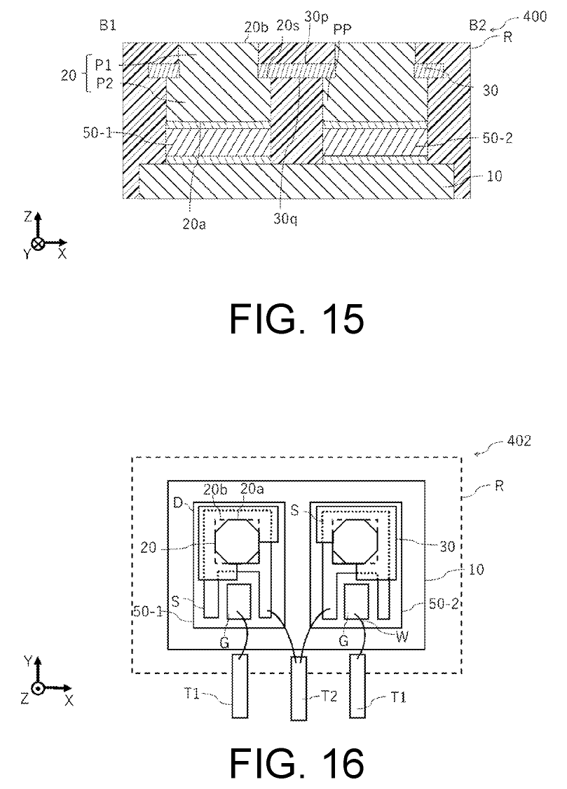

FIG. 13 is a perspective view of a semiconductor device 400 according to the fourth embodiment. Resin R is omitted in the illustration. FIG. 14A is a top view showing the semiconductor device 400 with resin R being transparent. FIG. 15 is an XZ cross-sectional view taken along line B1–B2 shown in FIG. 14A. Description of portions common to the semiconductor devices 100 to 300 of the first to third embodiments is partially omitted.

In the semiconductor device 400, the positional relationship between the second electrode 20 and the third electrode 30 differs from that in the semiconductor device 100 of the first embodiment. The second electrode 20 of the semiconductor device 400 includes a second portion P2 and a first portion P1 on the second portion P2. The area of the second surface 20b of the second electrode 20 in the XY plane is smaller than that of the first surface 20a. Since the second surface 20b is smaller than the first surface 20a, the second electrode 20 includes a step surface 20s as shown in FIG. 13. The step surface 20s is an upper surface of the second portion P2. The third electrode 30 overlaps and is connected to the second portion P2 of the second electrode 20 at the step surface 20s.

In FIG. 13, the second portion P2 of the second electrode 20 has a square shape in the XY plane, and the first portion P1 has an octagonal shape in the XY plane. The square second portion P2 has a larger area in the XY plane than the octagonal first portion P1. The third electrode 30 is connected to the second portion P2 in the vicinity of corners of the upper surface of the second portion P2. The first and second portions P1 and P2 are polygonal in a plane perpendicular to the Z direction, and the first portion P1 has a greater number of corners than the second portion P2 in the plane.

The third electrode 30 includes an intermediate portion 30M extending in the X direction and connecting a portion located above the first semiconductor element 50-1 and a portion located above the second semiconductor element 50-2. In FIG. 13, the second terminal T2 and the source electrode S are electrically connected via a wire W.

The third electrode 30 shown in FIG. 13 includes a notch. The notch above the first semiconductor element 50-1 is located in the positive direction of the X axis and the negative direction of the Y axis with respect to other parts of the third electrode 30 above the first semiconductor element 50-1. The step surface 20s of the second electrode 20 at the location of the notch of the third electrode 30 (not hidden by the third electrode 30 in FIG. 13) is not connected to the third electrode 30.

FIG. 14A is a top view showing the semiconductor device 400 with resin being transparent.

When the second portion P2 has a square shape in the XY plane, four step surfaces 20s are provided per second electrode 20. The third electrode 30 is electrically connected to the second electrode 20 at three of the four step surfaces 20s. In FIG. 14A, the step surface 20s closest to the second terminal T2 among the four step surfaces 20s is shown. That is, the step surface 20s closest to the second terminal T2 among the four step surfaces 20s physically contacts the resin R. On the other hand, the outlines of the remaining three step surfaces 20s are shown by dashed lines in FIG. 14A. The remaining three step surfaces 20s overlap with the third electrode 30 in the Z direction.

The second electrode 20 located above the first semiconductor element 50-1 and the second electrode 20 located above the second semiconductor element 50-2 each have four step surfaces located in the positive and negative directions of the X and Y axes relative to the centers of the respective second electrodes 20 in the XY plane. The second electrode 20 located above the first semiconductor element 50-1 is not connected to the third electrode 30 at the step surface 20s which is located in the positive direction of the X axis and the negative direction of the Y axis, and is in contact with the resin R. The second electrode 20 located above the second semiconductor element 50-2 is not connected to the third electrode 30 at the step surface 20s which is located in the negative direction of the X axis and the negative direction of the Y axis, and is in physical contact with the resin R.

As shown in the first modification of the fourth embodiment in FIG. 14B, a wire Wi (inter-electrode wire) connecting the source electrode S of the first semiconductor element 50-1 and the source electrode S of the second semiconductor element 50-2 may be further provided. The wire Wi electrically connects the source electrodes S of the first and second semiconductor elements. In the example shown in FIG. 14A, the source electrodes S of the first and second semiconductor elements are electrically connected via the third electrode 30. On the other hand, according to the configuration shown in FIG. 14B, the source electrodes S of the first and second semiconductor elements are electrically connected via the wire Wi in addition to the third electrode 30. Furthermore, even if the second electrode 20 and the third electrode 30 are bonded via an insulating material, electrical connection between the source electrodes S of the first and second semiconductor elements can be maintained. Although the semiconductor device 400 shown in FIG. 14A is described below, the wire Wi may also be provided.

FIG. 15 is an XZ cross-sectional view taken along line B1–B2 shown in FIG. 14A.

Referring to FIG. 15, the third electrode 30 is connected to the second electrode 20 at the step surface 20s. The third electrode 30 is in surface contact with and overlaps the second electrode 20 at the step surface 20s. In the fourth embodiment, the step surface 20s is a surface of the second electrode 20 oriented toward the positive direction of the Z axis.

The upper surface 30p of the third electrode 30 is provided closer to the semiconductor element 50 in the Z direction than the second surface 20b of the second electrode 20. The upper surface 30p of the third electrode 30 is located in the negative direction of the Z axis relative to the second surface 20b. The upper surface 30p of the third electrode 30 is located between the first surface 20a and the second surface 20b of the second electrode 20 in the Z direction.

The lower surface 30q of the third electrode 30 is the surface opposite to the upper surface 30p in the Z direction. The lower surface 30q faces at least a part of the step surface 20s of the second electrode 20. The lower surface 30q is provided farther from the semiconductor element 50 in the Z direction than the first surface 20a of the second electrode 20. The lower surface 30q is located in the positive direction of the Z axis relative to the first surface 20a. The lower surface 30q is located between the first surface 20a and the second surface 20b of the second electrode 20 in the Z direction. The upper surface 30p and the lower surface 30q of the third electrode 30 are located apart from both the first surface 20a and the second surface 20b of the second electrode 20 in the Z direction.

The second electrode 20 includes a second portion P2 and a first portion P1 on the second portion P2. The second portion P2 is located between the first portion P1 and the semiconductor element 50. The area of the first portion P1 in the XY plane is smaller than that of the second portion P2. The length of the first portion P1 in the X direction is smaller than that of the second portion P2. The step surface 20s is the upper surface of the protruding portion PP of the second portion P2 in the X direction. The third electrode 30 is provided on and overlaps the second portion P2. The third electrode 30 is located in the positive direction of the Z axis relative to the second portion P2. The third electrode 30 faces the protruding portion PP in the negative Z direction.

According to the configuration of the second electrode 20 and the third electrode 30 shown in the semiconductor device 400 of the fourth embodiment, a semiconductor device with reduced thermal resistance can be provided.

Furthermore, according to the semiconductor device 400 of the fourth embodiment, further miniaturization of the package is possible. The first terminal T1 and the second terminal T2 are connected to the gate electrode G and the source electrode S via wires W. In the manufacturing process, it is not necessary to bend the lead frame between the third electrode 30 and the second terminal T2, and between the fourth electrode 40 and the first terminal T1. The third electrode 30, the first terminal T1, and the second terminal T2 can be formed from a flat lead frame. By reducing the bent portions of the lead frame, the volume of resin R required for sealing the semiconductor package can be reduced.

Furthermore, according to the semiconductor device 400 of the fourth embodiment, interference between the third electrode 30 and the wire W in the manufacturing process can be suppressed. In the fourth embodiment, among the plurality of step surfaces 20s, the step surface 20s closest to the second terminal T2 is spaced apart from the third electrode 30. The third electrode 30 is spaced apart from the second terminal T2 by a sufficient distance. Therefore, when wire bonding is performed between the second terminal T2 and the source electrode S using a bonding tool, interference between the third electrode 30 and the bonding tool can be suppressed.

By configuring at least one of the step surfaces 20s to physically contact the resin R without being connected to the third electrode 30, interference between the second terminal T2 and the source electrode S during wire bonding process can be suppressed.

Additionally, another step surface 20s may be configured to physically contact the resin R. For example, two step surfaces 20s located in the negative direction of the Y axis with respect to the second electrode 20, may be configured not to connect to the third electrode 30. This further suppresses interference during wire bonding between the gate electrode G and the first terminal T1. On the other hand, as shown in FIG. 13, connecting the second electrode 20 and the third electrode 30 at three of the four step surfaces 20s is desirable for improving the positioning accuracy of the third electrode 30with respect to the second electrode 20 when placing the third electrode 30 on the second electrode 20 during manufacturing.

According to the semiconductor device 400 of the fourth embodiment, the second portion P2 includes a protruding portion PP that protrudes from the first portion P1 in the X and Y directions. The second portion P2 of the second electrode 20 protrudes into the resin R, resulting in strong adhesion between the resin R and the second electrode 20. For example, as shown in FIG. 15, peeling of the second electrode 20 from the resin R in the positive direction of the Z axis can be suppressed.

As shown in the second modification of the fourth embodiment in FIG. 16, the intermediate portion 30M may be omitted. On the other hand, providing the intermediate portion 30M is desirable for electrically connecting the source electrodes S of the first and second semiconductor elements 50-1 and 50-2. Alternatively, as shown in FIG. 14B, the source electrodes S of the first and second semiconductor elements 50-1 and 50-2 may be electrically connected via a wire Wi.

### Fifth Embodiment

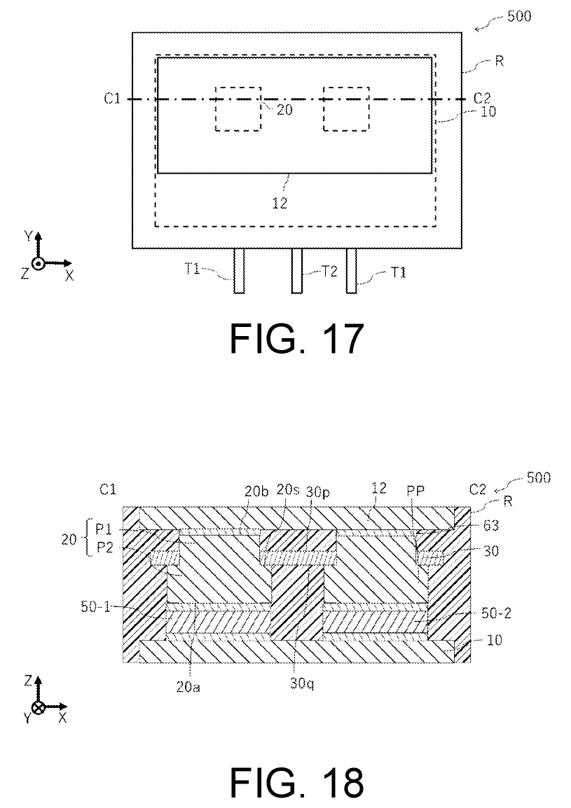

FIG. 17 is a top view of a semiconductor device 500 according to the fifth embodiment. FIG. 18 is an XZ cross-sectional view taken along line C1–C2 shown in FIG. 17. Description of portions common to the semiconductor device 100 of the first embodiment is partially omitted.

As shown in FIG. 17, an upper electrode 12 exposed from the resin R is provided. The upper electrode 12 is provided on the second electrode 20. An upper surface of the upper electrode 12 is exposed from the resin R.

In the cross-sectional view shown in FIG. 18, the second electrode 20 provided on the semiconductor element 50 and the upper electrode 12 provided on the second electrode 20 are shown. The second electrode 20 and the upper electrode 12 may be joined via a bonding layer 63, for example.

The second electrode 20 includes a first surface 20a facing the semiconductor element 50 and a second surface 20b facing the upper electrode 12. The second electrode 20 includes a second portion P2 and a first portion P1 on the second portion P2. The second portion P2 has a greater length in the X direction than the first portion P1 and includes a step surface 20s as the upper surface of the protruding portion PP.

The third electrode 30 is connected to the second electrode 20 at the step surface 20s. The upper surface 30p of the third electrode 30 is provided closer to the semiconductor element 50 in the Z direction than the second surface 20b of the second electrode 20. The upper surface 30p of the third electrode 30 is located in the negative direction of the Z axis relative to the second surface 20b. The upper surface 30p of the third electrode 30 is located between the first surface 20a and the second surface 20b of the second electrode 20 in the Z direction. The upper surface 30p of the third electrode 30 is spaced apart from the upper electrode 12 in the Z direction. Resin R is interposed between the upper surface 30p of the third electrode 30 and the upper electrode 12.

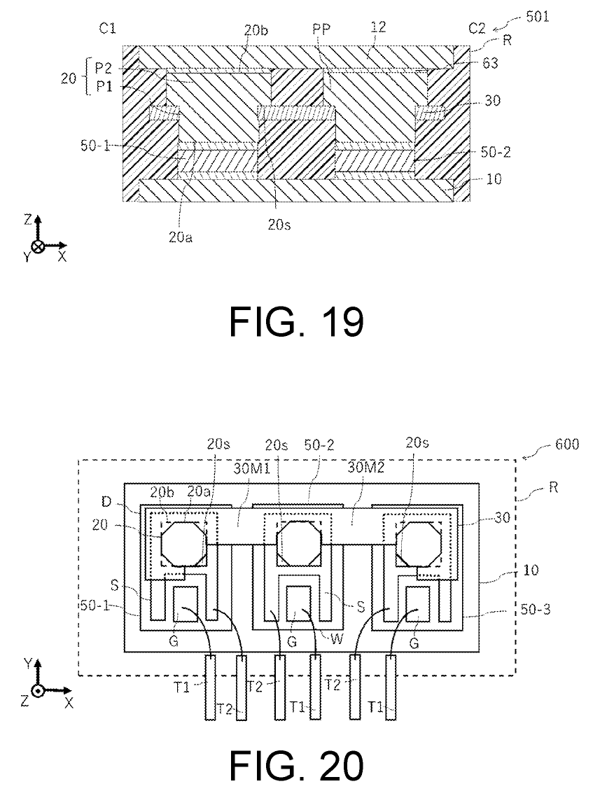

FIG. 19 shows a cross-sectional view of a semiconductor device 501 according to a first modification of the fifth embodiment. The cross-section in FIG. 19 corresponds to the cross-section along line C1–C2 shown in FIG. 17.

The second electrode 20 shown in FIG. 19 differs from that of the semiconductor device 500 in that the second portion P2 is located above the first portion P1. In the first modification of the fifth embodiment, the step surface 20s is the lower surface of the protruding portion PP of the second portion P2.

According to the semiconductor device 500 and the modified semiconductor device 501 of the fifth embodiment, miniaturization of the package is possible. The step surface 20s is located between the first surface 20a and the second surface 20b in the Z direction, and the Z-direction position of the step surface 20s can be appropriately selected by changing the shape of the second electrode 20. The Z-direction position of the third electrode 30 connected to the second electrode 20 at the step surface 20s can be adjusted. In the manufacturing process, the amount of bending steps for the lead frame can be reduced, including by eliminating the process of bending the lead frame between the third electrode 30 and the second terminal T2, and between the fourth electrode 40 and the first terminal T1. By reducing the number of bent portions of the lead frame, sealing with the resin R can be performed using a smaller volume of the resin R, enabling miniaturization of the package.

For comparison, consider a reference example in which the upper surface 30p of the third electrode 30 is provided at the same Z-direction position as the second surface 20b of the second electrode 20. That is, the upper surface 30p of the third electrode 30 and the second surface 20b of the second electrode 20 are provided on the same XY plane. In this reference example, the Z-direction position of the third electrode 30 can be determined by the Z-direction position of the second surface 20b of the second electrode 20.

The Z-direction positions of the first terminal T1 and the second terminal T2 may be determined by the package design. Therefore, in the reference example, bending of the lead frame including between the third electrode 30 and the second terminal T2, and between the fourth electrode 40 and the first terminal T1, may be required. When the lead frame is bent and the bent portion forms an obtuse angle, the size of the lead frame may increase. The volume of resin R required for sealing may also increase.

On the other hand, according to the semiconductor device 500 and the modified semiconductor device 501 of the fifth embodiment, the lead frame can be formed in a flat shape. Even if the Z-direction positions of the first and second terminals T1 and T2 shown in FIG. 17 are predetermined, the Z-direction position of the step surface 20s can be appropriately selected, and the Z-direction position of the third electrode 30 can be adjusted to be close to the Z-direction positions of the first and second terminals T1 and T2. The bending of the lead frame can be reduced, including between the third electrode 30 and the second terminal T2 and between the fourth electrode 40 and the first terminal T1, and the lead frame can be made closer to a flat shape or the number of bent portions can be reduced. Therefore, the amount of resin R required for sealing the package can be reduced, enabling miniaturization of the package.

### Sixth Embodiment

FIG. 20 is a top view showing a semiconductor device 600 according to the sixth embodiment with resin being transparent. Description of portions common to the semiconductor device 400 of the fourth embodiment is partially omitted.

The semiconductor device 600 includes three semiconductor elements 50: a first semiconductor element 50-1, a second semiconductor element 50-2, and a third semiconductor element 50-3. The three semiconductor elements 50 are arranged in the X direction. The semiconductor device 600 includes three second electrodes 20. The second electrodes 20 are provided on the semiconductor elements 50 and are arranged in the X direction.

The third electrode 30 located above the first semiconductor element 50-1 and the third electrode 30 located above the second semiconductor element 50-2 are physically connected via an intermediate portion 30M1. The third electrode 30 located above the second semiconductor element 50-2 and the third electrode 30 located above the third semiconductor element 50-3 are physically connected via an intermediate portion 30M2.

The second electrode 20 located above the first semiconductor element 50-1 includes four step surfaces 20s. Among these four step surfaces 20s, the step surface 20s located in the positive direction of the X axis and the negative direction of the Y axis is not connected to the third electrode 30. The second electrode 20 located above the first semiconductor element 50-1 is connected to and overlaps the third electrode 30 at three of the four step surfaces 20s.

The second electrode 20 located above the second semiconductor element 50-2 includes four step surfaces 20s. Among these four step surfaces 20s, the two step surfaces 20s located in the negative direction of the Y axis are not in contact with the third electrode 30. The second electrode 20 located above the second semiconductor element 50-2 is connected to and overlaps the third electrode 30 at two of the four step surfaces 20s.

The second electrode 20 located above the third semiconductor element 50-3 includes four step surfaces 20s. Among these four step surfaces 20s, the step surface 20s located in the negative direction of the X axis and the negative direction of the Y axis is not in physical contact with the third electrode 30. The second electrode 20 located above the third semiconductor element 50-3 is connected to and overlaps the third electrode 30 at three of the four step surfaces 20s.

When three or more second electrodes 20 are provided as in the semiconductor device 600 of the sixth embodiment, the number of step surfaces 20s connected to the third electrode 30 in one second electrode 20 may differ from that in another second electrode 20. The ratio of the number of step surfaces 20s connected to the third electrode 30 to the total number of step surfaces 20s in one second electrode 20 may differ from that in another second electrode 20.

In the example shown in FIG. 20, the number of step surfaces 20s connected to the third electrode 30 in the second electrode 20 located above the second semiconductor element 50-2 is smaller than that in the second electrode 20 located above the first or third semiconductor element 50-1 or 50-3.

According to the semiconductor device 600 of the sixth embodiment, a semiconductor device with reduced thermal resistance can be provided.

Furthermore, according to the semiconductor device 600 of the sixth embodiment, for the second electrode 20 above the second semiconductor element 50-2, the step surfaces 20s located in the negative direction of the Y axis of are not connected to the third electrode 30. This suppresses interference between the third electrode 30 and the bonding tool when connecting the source electrode S of the second semiconductor element 50-2 to the second terminal T2 via a wire W. It also suppresses interference between the third electrode 30 and the bonding tool when connecting the gate electrode G of the second semiconductor element 50-2 to the first terminal T1 via a wire W.

### Seventh Embodiment

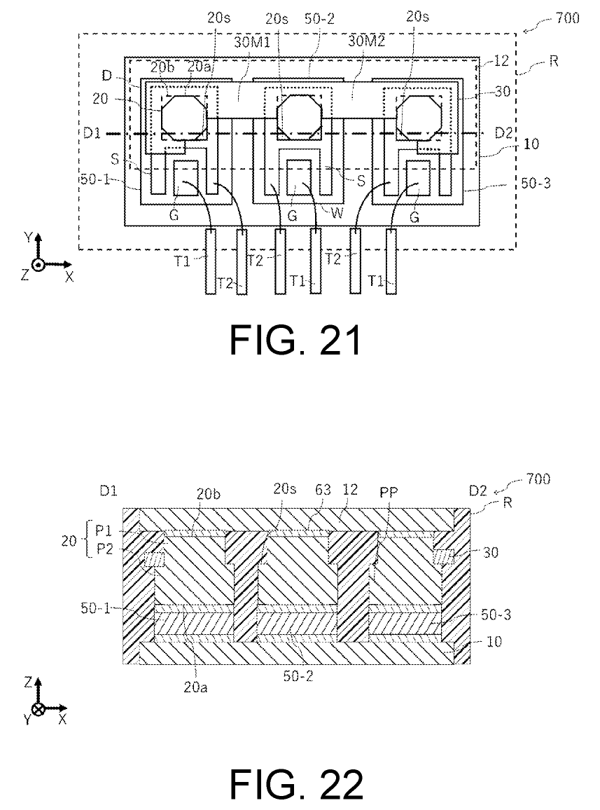

FIG. 21 is a top view showing a semiconductor device 700 according to the seventh embodiment with resin being transparent. FIG. 22 is an XZ cross-sectional view taken along line D1–D2 shown in FIG. 21. Description of portions common to the semiconductor device 600 of the sixth embodiment is partially omitted.

The semiconductor device 700 includes an upper electrode 12 located above the second electrode 20. The upper electrode 12 is exposed from the resin R. As shown in FIG. 22, the upper electrode 12 is located above three or more second electrodes 20 with a bonding layer 63 interposed therebetween and is exposed from the resin R.

According to the semiconductor device 700 of the seventh embodiment, a semiconductor device with reduced thermal resistance can also be provided.

According to at least one of the semiconductor devices of the first to seventh embodiments described above, a semiconductor device with reduced thermal resistance can be provided. Furthermore, quality control of the semiconductor device can be improved, and reliability thereof can be further enhanced. Additionally, according to at least one of the semiconductor devices of the first to seventh embodiments described above, miniaturization of the package is possible.

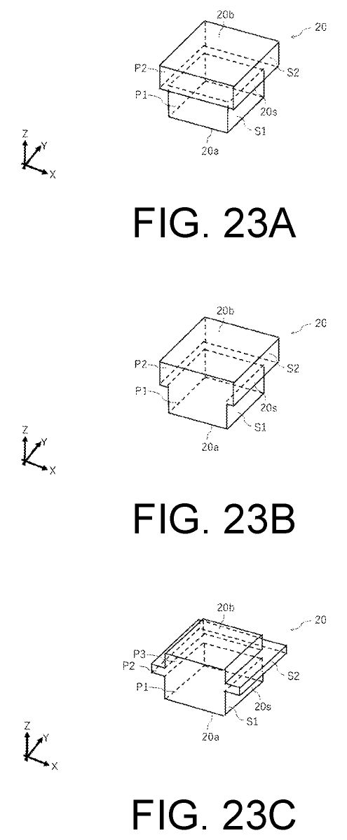

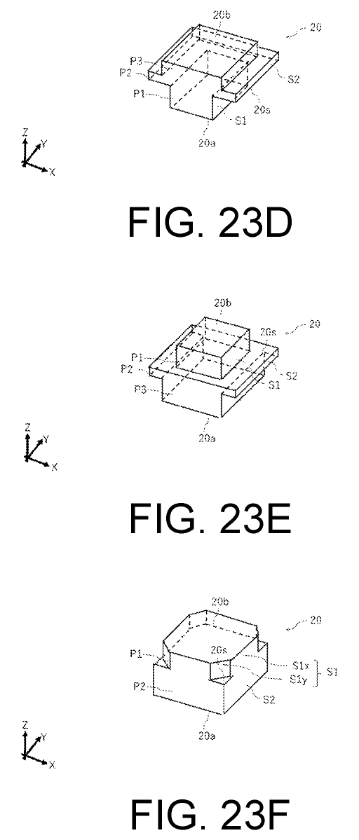

FIGS. 23A–23F show perspective views of examples of the second electrode 20.

FIG. 23A shows, for example, the second electrode 20 shown in FIG. 2B. The second portion P2 is located on the first portion P1, and the lower surface of the second portion P2 is the step surface 20s. The step surface 20s is located between the first side surface S1 and the second side surface S2 and connects the first side surface S1 and the second side surface S2. The second portion P2 includes a protruding portion protruding further than any part of the first portion P1 in the X direction and a protruding portion protruding further than any part of the first portion P1 in the Y direction.

As shown in FIG. 23B, a side surface of the second electrode 20 located in the negative direction of the Y axis and perpendicular to the Y direction may be formed to be flat and to extend across the first portion P1 and the second portion P2. Among side surfaces of the second electrode 20, despite only illustrating a single flat surface in FIG. 23B, there may instead be two or three flat surfaces, i.e., at least one side surface including a step surface 20s.

FIG. 23C shows, for example, the second electrode 20 shown in FIG. 9. The second portion P2 is located on the first portion P1, and the third portion P3 is located on the second portion P2. The lower surface of the second portion P2 is the step surface 20s. Alternatively, the second electrode 20 shown in FIG. 23C may be inverted so that the upper surface of the second portion P2 becomes the step surface 20s, resulting in the second electrode 20 shown in FIG. 11.

As shown in FIG. 23C, a side surface of the second electrode 20 located in the negative direction of the Y axis and perpendicular to the Y direction may be formed to be flat and to extend across the first portion P1, the second portion P2, and the third portion P3.

FIG. 23D shows another example of the second electrode 20 shown in FIG. 9. The length of the first portion P1 in the X direction is smaller than that of the third portion P3, and the length of the third portion P3 in the X direction is smaller than that of the second portion P2. The lower surface of the second portion P2 is the step surface 20s. According to the second electrode 20 shown in FIG. 23D, the area of the step surface 20s can be increased, and the contact area between the second electrode 20 and the third electrode 30 can be enlarged. Furthermore, because the area of the second surface 20b is larger than that of the first surface 20a, a larger contact area of the second surface 20b exposed from the resin R can be achieved for electrical connection to an external circuit outside the package.

FIG. 23E shows another example of the second electrode 20 shown in FIG. 11. The second portion P2 is located on the third portion P3, and the first portion P1 is located on the second portion P2. The length of the first portion P1 in the X direction is smaller than that of the third portion P3, and the length of the third portion P3 in the X direction is smaller than that of the second portion P2. The area of the first surface 20a is larger than that of the second surface 20b. The length of the first portion P1 in the Y direction is smaller than that of the third portion P3. The upper surface of the second portion P2 is the step surface 20s. According to the second electrode 20 shown in FIG. 23E, the area of the step surface 20s can be increased, and the contact area between the second electrode 20 and the third electrode 30 can be enlarged. A side surface of the second electrode 20 located in the negative direction of the Y axis and perpendicular to the Y direction, may be formed to be flat and to extend across the second portion P2, and the third portion P3.

FIG. 23F shows, for example, the second electrode 20 shown in FIG. 13. The first portion P1 is located above the second portion P2. The area of the first surface 20a is larger than that of the second surface 20b. The step surface 20s is the upper surface of the second portion P2.

The first surface 20a, the second surface 20b, and the step surface 20s have polygonal shapes. The corners of the polygons may be rounded. The first surface 20a may be, for example, square. The second surface 20b may be, for example, octagonal. The step surface 20s may be, for example, triangular.

The first side surface S1 includes a first region S1x parallel to the second side surface S2 and a second region S1y continuous with the step surface 20s. In FIG. 23F, the second region S1y of the first side surface S1 extending in a direction that intersects a direction in which the second side surface S2 extends. The step surface 20s connects the second region S1y and the second side surface S2. The combined shape of the first region S1x of the first side surface S1 and the second side surface S2 may be, for example, a stacked shape of a wide first rectangle and a narrow second rectangle.

The dimensional relationship between the first portion P1 and the second portion P2 of the second electrode 20 shown in FIGS. 23A–23F is not limited to those illustrated. Furthermore, the second electrode 20 shown in FIGS. 23A–23F may be provided upside down with respect to the illustrated examples.

The embodiments have been described above with reference to specific examples. However, the embodiments are not limited to these specific examples. In other words, designs obtained by appropriately modifying these specific examples by a person skilled in the art are also included within the scope of the embodiments as long as the designs have the novel characteristics of the embodiments. Each element provided in each of the specific examples described above, and the arrangement, material, condition, shape, size, and the like thereof is not limited to that described in the examples, and can be modified as appropriate.

Furthermore, the respective elements described for different embodiments can be combined with each other to the extent technically feasible, and the combinations thereof are also included within the scope of the present disclosure. In addition thereto, within the scope of the present disclosure, various modifications and alterations will be apparent to a person skilled in the art, and it is to be understood that these modifications and alterations also fall within the scope of the present disclosure.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a first electrode;
a first semiconductor element provided on the first electrode;
a second electrode provided on the first semiconductor element, the second electrode having a lower surface facing the first semiconductor element, and having an upper surface opposite to the lower surface of the second electrode; and
a third electrode overlapping the second electrode in a first direction that extends from the first electrode toward the first semiconductor element, a lower surface of the third electrode being located farther from the first semiconductor element than the lower surface of the second electrode in the first direction, and an upper surface of the third electrode being located closer to the first semiconductor element than the upper surface of the second electrode in the first direction.

2. The semiconductor device according to claim 1, further comprising:
a resin surrounding the first semiconductor element in a plane perpendicular to the first direction, wherein
a lower surface of the first electrode is exposed from the resin, and
the upper surface of the second electrode is exposed from the resin.

3. The semiconductor device according to claim 1, further comprising:
an upper electrode provided on the second electrode; and
a resin surrounding the first semiconductor element and the second electrode in a plane perpendicular to the first direction, a lower surface of the first electrode and an upper surface of the upper electrode being exposed from the resin.

4. The semiconductor device according to claim 1, wherein
the second electrode includes
a first portion, and
a second portion on the first portion, and
the third electrode faces a step surface of the second electrode, the step surface physically connecting a first side surface of the first portion and a second side surface of the second portion, the first and second side surfaces extending in the first direction, and the step surface extending in a direction intersecting the first direction.

5. The semiconductor device according to claim 4, wherein the first portion is located between the first semiconductor element and the second portion, and the step surface faces a direction opposite to the first direction.

6. The semiconductor device according to claim 4, wherein the step surface and the third electrode overlap in the first direction with a conducting material interposed therebetween.

7. The semiconductor device according to claim 4, wherein the step surface and the third electrode overlap in the first direction with an insulating material interposed therebetween.

8. The semiconductor device according to claim 1, wherein the third electrode is a plate-shaped conductor extending in a direction perpendicular to the first direction without bending.

9. The semiconductor device according to claim 1, wherein
the second electrode includes
a first portion, and
a second portion having a greater length than the first portion in a second direction intersecting the first direction, and
the third electrode overlaps the second portion of the second electrode in the first direction.

10. The semiconductor device according to claim 9, wherein
the second portion includes a first protruding portion protruding further than any part of the first portion in the second direction,
the first portion is located closer to the first semiconductor element than the second portion, and
the third electrode overlaps the first protruding portion in the first direction.

11. The semiconductor device according to claim 10, wherein the second portion further includes a second protruding portion protruding further than any part of the first portion in a third direction intersecting both the first and second directions.

12. The semiconductor device according to claim 10, wherein the second electrode includes a side surface perpendicular to a third direction intersecting both the first and second directions, the side surface of the second electrode being flat and extending across the first and second portions.

13. The semiconductor device according to claim 9, wherein
the second portion includes a protruding portion protruding further than any part of the first portion in the second direction,
the first portion is located farther from the first semiconductor element than the second portion, and
the third electrode overlaps the protruding portion in the first direction.

14. The semiconductor device according to claim 13, wherein the first and second portions are each polygonal in a plane perpendicular to the first direction, and the first portion has a greater number of corners than the second portion in the plane.

15. The semiconductor device according to claim 9, wherein
the second electrode further includes a third portion, the second portion being provided between the first and third portions, and
the second portion includes a protruding portion protruding further than any part of the third portion in the second direction.

16. The semiconductor device according to claim 15, wherein the second electrode includes a side surface perpendicular to a third direction intersecting both the first and second directions, the side surface of the second electrode being flat and extending across the second and third portions.

17. The semiconductor device according to claim 1, further comprising:
a source electrode on the first semiconductor element;
a resin surrounding the first semiconductor element in a plane perpendicular to the first direction;
a terminal exposed from the resin; and
a wire electrically connecting the source electrode and the terminal.

18. The semiconductor device according to claim 1, further comprising:
a source electrode on the first semiconductor element;
a resin surrounding the first semiconductor element in a plane perpendicular to the first direction; and
a terminal exposed from the resin, wherein
the third electrode and the terminal are formed as a single member, and
the third electrode is electrically connected to the source electrode via the second electrode.

19. The semiconductor device according to claim 1, further comprising:
a second semiconductor element provided on the first electrode;
a fourth electrode provided on the second semiconductor element, the fourth electrode overlapping the third electrode in the first direction, the fourth electrode having a lower surface facing the second semiconductor element, and an upper surface opposite to the lower surface of the fourth electrode, wherein
the lower surface of the third electrode is located farther from the second semiconductor element than the lower surface of the fourth electrode in the first direction, and
the upper surface of the third electrode is located closer to the second semiconductor element than the upper surface of the fourth electrode in the first direction.

20. The semiconductor device according to claim 19, further comprising:
a third semiconductor element provided on the first electrode;
a fifth electrode provided on the third semiconductor element, the fifth electrode overlapping the third electrode in the first direction, the fifth electrode having a lower surface facing the third semiconductor element, and an upper surface opposite to the lower surface of the fifth electrode, wherein
the lower surface of the third electrode is located farther from the third semiconductor element than the lower surface of the fifth electrode in the first direction, and
the upper surface of the third electrode is located closer to the third semiconductor element than the upper surface of the fifth electrode in the first direction.
